(19) United States
(12) Patent Application Publication
(10) Pub. No.: US 2015/0046775 A1
(43) Pub. Date: Feb. 12, 2015

(54) Encoding and Decoding Schemes to Achieve Standard Compliant Mean Time to False Packet Acceptance

(71) Applicant: Broadcom Corporation, Irvine, CA (US)

(72) Inventors: Richard Prodan, Niwot, CO (US); Bazhong Shen, Irvine, CA (US); Mark Laubach, Redwood City, CA (US)

(73) Assignee: Broadcom Corporation, Irvine, CA (US)

(21) Appl. No.: 14/454,393

(22) Filed: Aug. 7, 2014

Related U.S. Application Data
(60) Provisional application No. 61/863,039, filed on Aug. 7, 2013.
(60) Provisional application No. 61/877,226, filed on Sep. 12, 2013.

(51) Int. Cl. H04L 1/00; H03M 13/11; H04B 10/27

(52) U.S. Cl. CPC H04L 1/0076; H04B 10/27; H03M 13/1105
USPC 714/776

(57) ABSTRACT

Systems and methods for enabling encoding/decoding schemes that satisfy the IEEE 802.3 Mean Time To False Packet Acceptance (MTTFPA) requirement in an Ethernet Passive Optical Network over Coax (EPoC) are described. The proposed encoding/decoding schemes assume existing Medium Access Control (MAC) layer Cyclic Redundancy Check (CRC) encoding/decoding, thereby requiring no changes in the Ethernet Passive Optical Network (EPON) MAC protocol, but increase error protection in the EPoC physical layer (PHY) to meet the MTTFPA requirement without sacrificing desired Ethernet frame loss ratios and downstream/upstream data rates for EPoC.

### CROSS-REFERENCE TO RELATED APPLICATION(S)

The present application claims the benefit of U.S. Provisional Application No. 61/863,039, filed Aug. 7, 2013, and U.S. Provisional Application No. 61/877,226, filed Sep. 12, 2013, both of which are incorporated herein by reference in their entireties.

### TECHNICAL FIELD

The present disclosure relates generally to Ethernet Passive Optical Network over Coax (EPoC).

### BACKGROUND

A Mean Time To False Packet Acceptance (MTTFPA) requirement of the IEEE 802.3 standards requires that the average time between two erroneous Ethernet frames traversing the physical layer and being accepted by the Medium Access Control (MAC) layer as valid should be greater than the lifetime of the universe (estimated at 14 billion years).

### BRIEF DESCRIPTION OF THE DRAWINGS/FIGURES

The accompanying drawings, which are incorporated herein and form a part of the specification, illustrate the present disclosure and, together with the description, further serve to explain the principles of the disclosure and to enable a person skilled in the pertinent art to make and use the disclosure.

FIG. 1 illustrates an example Ethernet Passive Optical Network over Coax (EPoC) environment in which embodiments can be implemented or practiced.

FIG. 2 illustrates an example implementation of the EPoC environment of FIG. 1.

FIG. 3 illustrates another example implementation of the EPoC environment of FIG. 1.

FIGS. 4A-4B, 5A-5B, 6A-6B, and 7A-7B illustrate example physical layer (PHY) devices according to embodiments.

FIG. 8 illustrates an example PHY encoding process according to an embodiment.

FIG. 9 illustrates an example PHY decoding process according to an embodiment.

The present disclosure will be described with reference to the accompanying drawings. Generally, the drawing in which an element first appears is typically indicated by the leftmost digit(s) in the corresponding reference number.

### DETAILED DESCRIPTION OF EMBODIMENTS

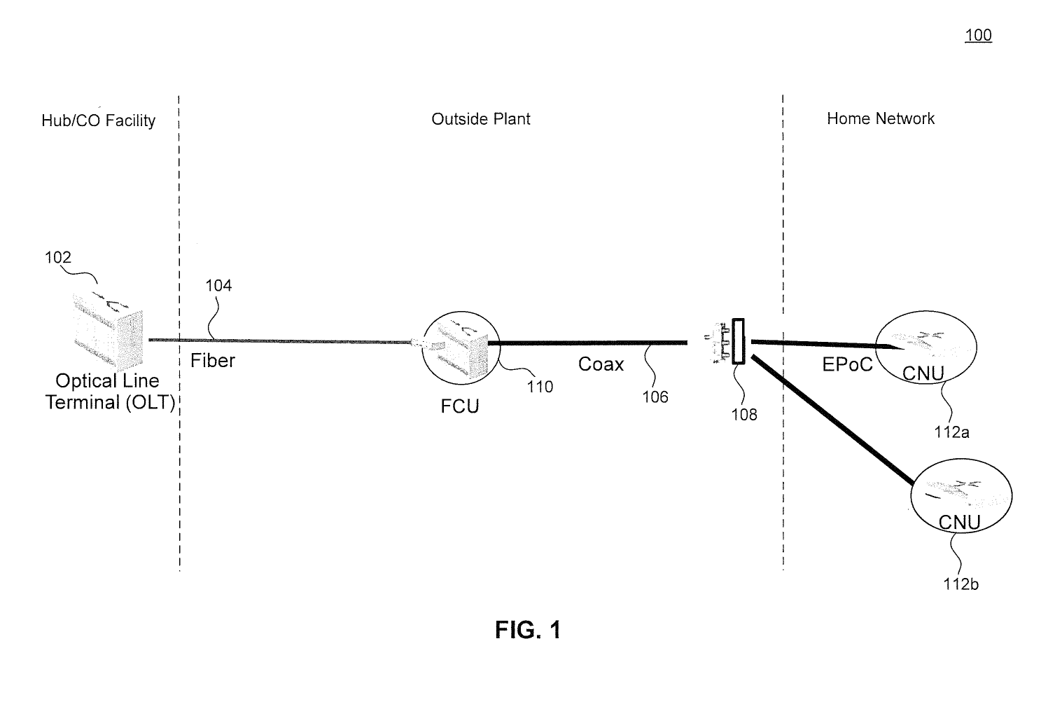

FIG. 1 illustrates an example Ethernet Passive Optical Network over Coax (EPoC) environment 100 in which embodiments can be implemented or practiced. Example EPoC environment 100 is provided for the purpose of illustration only and is not limiting of embodiments. As would be understood by a person of skill in the art based on the teachings herein, in other embodiments, example environment 100 can include more or less components than illustrated in FIG. 1.

As shown in FIG. 1, example environment 100 includes an Optical Line Terminal (OLT) 102, a Fiber Coax Unit (FCU) 110, a splitter 108, and Coaxial Network Units (CNUs) 112a and 112b. OLT 102 is coupled to FCU 110 via a fiber optic line 104. FCU 110 is coupled to CNUs 112a and 112b via a coaxial cable 106 and splitter 108.

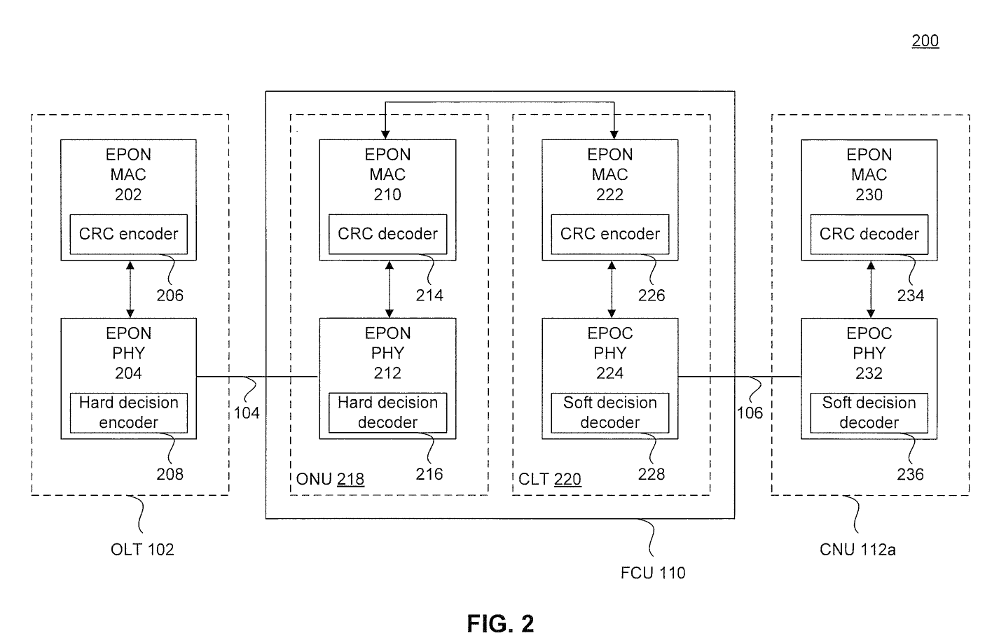

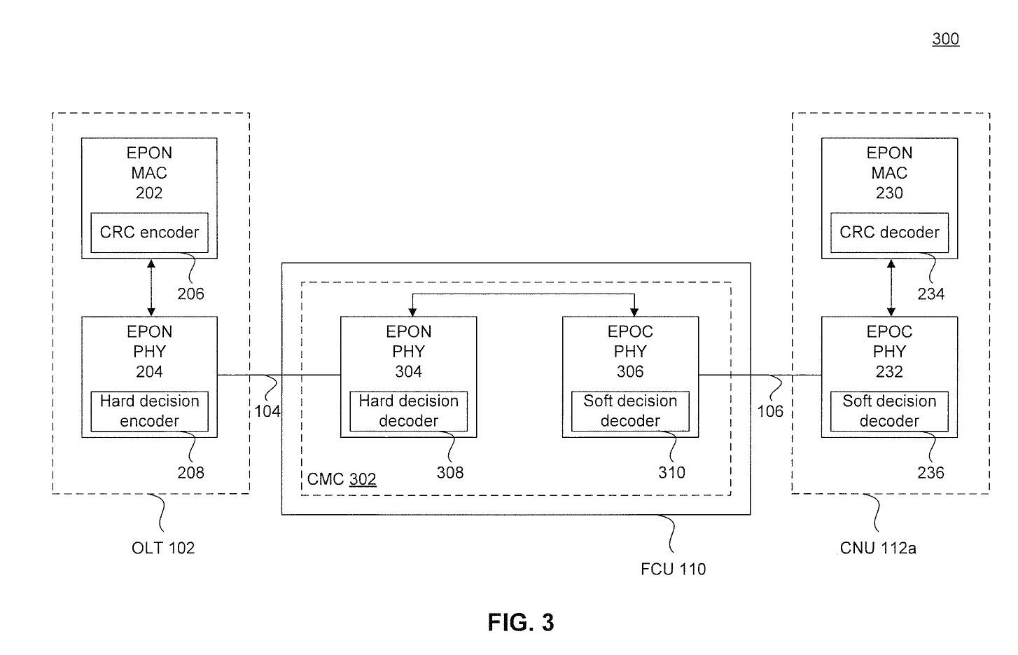

FCU 110 performs conversion from optical to electrical, and vice versa, to enable communication between OLT 102 and CNUs 112a and 112b. FCU 110 can be implemented according to various configurations as illustrated in FIGS. 2 and 3 described below, each of which illustrates an example implementation of example EPoC environment 100.

In example implementation 200 shown in FIG. 2, FCU 110 is implemented according to a bridge configuration. As such, FCU 110 includes an Optical Network Unit (ONU) 218 and a Coaxial Line Terminal (CLT) 220. ONU 218 includes processing circuitry for implementing an Ethernet Passive Optical Network (EPON) MAC 210 and an underlying EPON physical layer (PHY) 212. CLT 220 includes processing circuitry for implementing an EPON MAC 222 and an underlying EPoC PHY 224. OLT 102 includes processing circuitry for implementing an EPON MAC 202 and an underlying EPON PHY 204. CNU 112a includes processing circuitry for implementing an EPON MAC 230 and an underlying EPoC PHY 232.

According to this configuration, communication over the coaxial portion of the network is transparent to OLT 102. Specifically, when an upstream transmission request (e.g., EPON Report frame) from CNU 112a is received by CLT 220, the upstream transmission request is forwarded to EPON MAC 222. EPON MAC 222 responds to the upstream transmission request by issuing an upstream transmission grant (e.g., EPON GATE frame) to CNU 112a. The upstream transmission grant indicates an upstream transmission time over coaxial cable 106. CNU 112a transmits upstream data at the indicated upstream transmission time over coaxial cable 106. The upstream data from CNU 112a is received by CLT 220 and forwarded to EPON MAC 222. EPON MAC 222 extracts the Ethernet frames contained in the upstream data from CNU 112a and forwards the Ethernet frames to EPON MAC 210 of ONU 218.

EPON MAC 210 of ONU 218 has an EPON MAC link established with EPON MAC 202 of OLT 102. To deliver the Ethernet traffic of CNU 112a, EPON MAC 212 sends an upstream transmission request (e.g., EPON Report frame) to OLT 102. In response, EPON MAC 202 of OLT 102 issues to EPON MAC 210 an upstream transmission grant (e.g., EPON GATE frame) indicating an upstream transmission time over fiber optic line 104. ONU 218 transmits upstream data containing the Ethernet traffic of CNU 112a at the indicated upstream transmission time over fiber optic line 104.

In the downstream, data is transmitted from EPON MAC 202 of OLT 102 to EPON MAC 210 of ONU 218. EPON MAC 210 extracts the Ethernet frames contained in the downstream data from OLT 102 and forwards the Ethernet frames to EPON MAC 222 of CLT 220. EPON MAC 222 determines and forwards the Ethernet frames to the intended CNU recipient.

To achieve a desired error performance at the destination, in the downstream, Ethernet frames (e.g., EPON Ethernet frames) are encoded at EPON MAC 202 by a Cyclic Redundancy Check (CRC) encoder 206. The output of EPON MAC 202 is then further encoded at EPON PHY 204 by a hard decision encoder 208, before being transmitted over fiber optic line 104. Hard decision encoder 208 can be a Reed-Solomon encoder, for example. At ONU 218, received downstream data is decoded at EPON PHY 212 using a hard decision decoder 216. The resulting data stream is then CRC decoded using a CRC decoder 214 at EPON MAC 210 to retrieve the Ethernet frames transmitted by OLT 102. The Ethernet frames are then forwarded from EPON MAC 210 to EPON MAC 222 as described above. In EPON MAC 222, CRC encoding is applied to the Ethernet frames using a CRC encoder 226, and the resulting data stream is forwarded to EPoC PHY 224. At EPoC PHY 224, the data stream is encoded using a soft decision encoder 228, before being transmitted over coaxial cable 106. Soft decision encoder 228 can be a Low Density Parity Check (LDPC) encoder. At CNU 112a, received downstream data is decoded at EPoC PHY 232 using a soft decision decoder 236. The resulting data stream is then CRC decoded using a CRC decoder 234 at EPON MAC 230 to retrieve the Ethernet frames. Reverse processing is performed for upstream data as would be understood by a person of skill in the art based on the teachings herein.

In example implementation 300 shown in FIG. 3, FCU 110 is implemented in a managed repeater configuration. As such, FCU 110 includes processing circuitry for implementing an EPON PHY 304 and an EPoC PHY 306. EPON PHY 304 and EPoC PHY 306 are coupled to each other and together form a Coaxial Media Converter (CMC) 302. EPON PHY 304 connects FCU 110 via optical fiber line 104 to OLT 102. EPoC PHY 310 connects FCU 110 via coaxial cable 106 to CNU 112a. OLT 102 and CNU 112a are implemented as described above with respect to FIG. 2.

In this configuration, an EPON MAC link is established end-to-end between EPON MAC 202 of OLT 102 and EPON MAC 230 of CNU 112a, and FCU 110 acts as a PHY level converter between the optical and coaxial portions of the network. Specifically, when upstream data, e.g., containing an upstream transmission request (e.g., EPON Report frame), from CNU 112a is received by FCU 110, the upstream data is processed by EPoC PHY 306 to remove a coaxial line encoding and then provided to EPON PHY 304. EPON PHY 304 line encodes the upstream data for optical transmission and then transmits the upstream data over optical fiber line 104 to OLT 102. In response to the upstream transmission request, EPON MAC 202 of OLT 102 issues an upstream transmission grant (e.g., EPON GATE frame) to CNU 112a. The upstream time grant is transmitted in downstream data by EPON PHY 204 to FCU 110. In FCU 110, the downstream data is processed by EPON PHY 304 to remove an optical line encoding and then provided to EPoC PHY 306. EPoC PHY 306 adds a coaxial line encoding to the downstream data and then transmits the downstream data to CNU 112a. The downstream data is received by CNU 112a and the upstream time grant is forwarded to EPON MAC 230. CNU 112a then transmits upstream data in accordance with the upstream time grant.

Error protection processing is similar to example implementation 200 described above. Specifically, in OLT 102, Ethernet frames are encoded at EPON MAC 202 by CRC encoder 206, and the output of EPON MAC 202 is further encoded at EPON PHY 202 by hard decision encoder 208. At FCU 110, EPON PHY 304 includes a hard decision decoder 308 that performs hard decision decoding on received downstream data and that forwards the resulting downstream data to EPoC PHY 306. At EPoC PHY 306, a soft decision encoder 310 encodes the downstream data before transmission over coaxial cable 106 to CNU 112a. At CNU 112a, the received downstream data is decoded using soft decision decoder 236. The resulting data stream is forwarded to EPON MAC 230, where it is decoded using CRC decoder 234 to retrieve the Ethernet frames transmitted by OLT 102. Reverse processing is performed for upstream data as would be understood by a person of skill in the art based on the teachings herein.

As can be seen from example implementations 200 and 300, error protection over the coaxial portion of an EPoC network (for both upstream and downstream data) is realized using CRC encoding/decoding applied at the EPON MAC and soft decision encoding/decoding applied at the EPoC PHY. Typically, EPON MAC CRC encoding/decoding includes adding a 32-bit CRC per Ethernet frame. Soft decision PHY encoding/decoding in EPoC is done using a (16200, 14400) LDPC code for the downstream and using a (16200, 14400), a (5940, 5040), or a (1120, 840) LDPC code in the upstream.

However, the error performance that can be achieved using this encoding/decoding scheme is insufficient to support desired Ethernet frame loss ratios (10⁻⁶ in the downstream, 5×10⁻⁵ in the upstream) at the envisioned downstream/upstream data rates (10 Gbps) for EPoC. In particular, the described encoding/decoding scheme fails to achieve a desired Mean Time to False Packet Acceptance (MTTFPA) required by the IEEE 802.3 standards. The MTTFPA requirement specifies that the average time between two erroneous Ethernet frames traversing the PHY (i.e., with the PHY decoder incorrectly decoding a transmitted FEC codeword as another valid FEC codeword) and being accepted by the MAC as valid (i.e., with the CRC check indicating a correct CRC) should be greater than the lifetime of the universe (14 billion years).

In the following, systems and methods for enabling encoding/decoding schemes that satisfy the MTTFPA requirement in EPoC are described according to embodiments. The proposed encoding/decoding schemes assume similar MAC layer CRC encoding/decoding as described above, thereby requiring no changes in the EPON MAC, but increase error protection in the EPoC PHY layer to meet the MTTFPA requirement without sacrificing the desired Ethernet frame loss ratios and downstream/upstream data rates for EPoC.

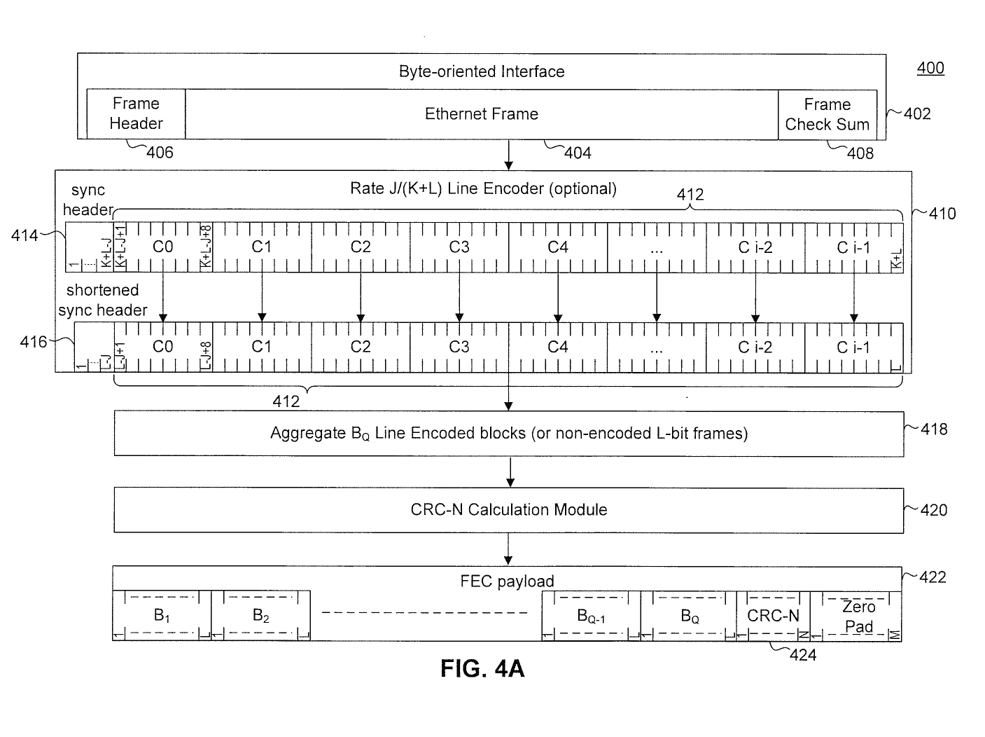

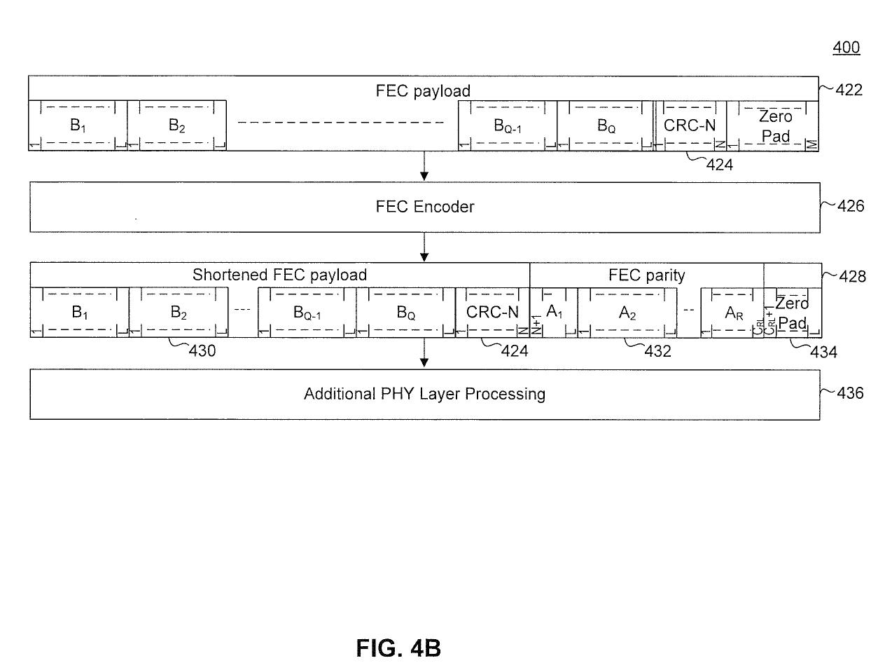

FIGS. 4A-4B illustrate an example PHY device 400 according to an embodiment. Example PHY device 400 is provided for the purpose of illustration only and is not limiting of embodiments. Example PHY device 400 can be an embodiment of EPoC PHY 224, EPoC PHY 232, or EPoC PHY 306 described above, and can be used to perform a PHY encoding scheme according to an embodiment. In an embodiment, PHY device 400 includes interface circuitry 402 and processing circuitry for implementing at least a line encoder 410, a buffer 418, a CRC-N calculation module 420, a Forward Error Correction (FEC) encoder 426, and a lower PHY processing module 436.

As shown in FIG. 4A, operation in PHY device 400 begins with interface circuitry 402 receiving a stream of MAC frames from a MAC layer module. The MAC layer module can be an EPON MAC module, such as EPON MAC 222 or EPON MAC 230. Alternatively, interface circuitry 402 can be configured to receive the stream of MAC frames from a PHY layer module, as in the case of EPoC PHY 306 in FCU 110 described in FIG. 3. In an embodiment, interface circuitry 402 includes a byte-oriented interface (e.g., MII, GMII, XGMII, etc.), where the stream of MAC frames is transferred byte-wise across the interface. In an embodiment, as shown in FIG. 4A, a MAC frame transferred across interface circuitry 402 includes a frame header 406, an Ethernet frame 404, and a Frame Check Sum (FCS) 408. Frame header 406 can be an EPON header, for example. FCS 408 is a 32-bit CRC sequence which can be used to detect communication errors in Ethernet frame 404.

Optionally, a plurality of J-bit data blocks are assembled from the stream of MAC frames. The J-bit data blocks are then line encoded using a rate J/(K+L) line encoder 410. As shown in FIG. 4A, the line encoding of a J-bit data block 412 in line encoder 410 results in the addition of a K+L−J synchronization header 414 to J-bit data block 412, resulting in a data block of total size K+L. In an embodiment, synchronization header 414 is shortened by removing K bits to result in a shortened header 416 of size L−J for each J-bit data block 412 and a data block of total size L. In another embodiment, no line encoding is performed on the stream of MAC frames, and instead a plurality of L-bit data blocks are assembled from the stream of MAC frames.

The L-bit data blocks output from line encoder 410 or resulting from the assembly of the stream of MAC frames into L-bit data blocks are then input into a buffer 418, which aggregates B_{Q} L-bit data blocks and provides the aggregated data blocks to a CRC-N calculation module 420.

In CRC-N calculation module 420, an N-bit CRC is performed on the B_{Q} data blocks, and a calculated N-bit CRC sequence 424 is appended to the B_{Q} data blocks to form an FEC payload 422 of an FEC codeword. In an embodiment, the B_{Q} data blocks and the N-bit CRC sequence 424 are padded with M zeros if necessary up to an FEC payload size (k information bits). It is noted that FEC payload 422 can include one or more Ethernet frames depending on the sizes of Ethernet frames contained in the received stream of MAC frames.

Then, as shown in FIG. 4B, FEC payload 422 is provided to FEC encoder 426, which encodes FEC payload 422 to generate an FEC codeword 428. In an embodiment, FEC encoder 426 is an (n, k) encoder which computes (n−k) FEC parity bits 432 in A_{R} blocks based on FEC payload 422. In another embodiment, FEC encoder 426 can be a non-binary (p, q) FEC encoder with s-bit symbols, where n=p*s and k=q*s. FEC parity bits 432 are then appended to a shortened FEC payload 430 obtained by removing the zero padding from FEC payload 422. The resulting shortened codeword is then zero padded if necessary with L−C_{RL} bits 434 to form FEC codeword 428 comprising B_{Q}+A_{R} L-bit blocks. In an embodiment, L−N+(R−2)L+C_{RL}=n−k. Alternatively, padding can be used to align to a byte boundary, or no padding is added if no boundary alignment of codewords is needed.

Finally, FEC codeword 428 is output to lower PHY processing module 436 for additional physical layer processing prior to transmission over the coaxial cable interface.

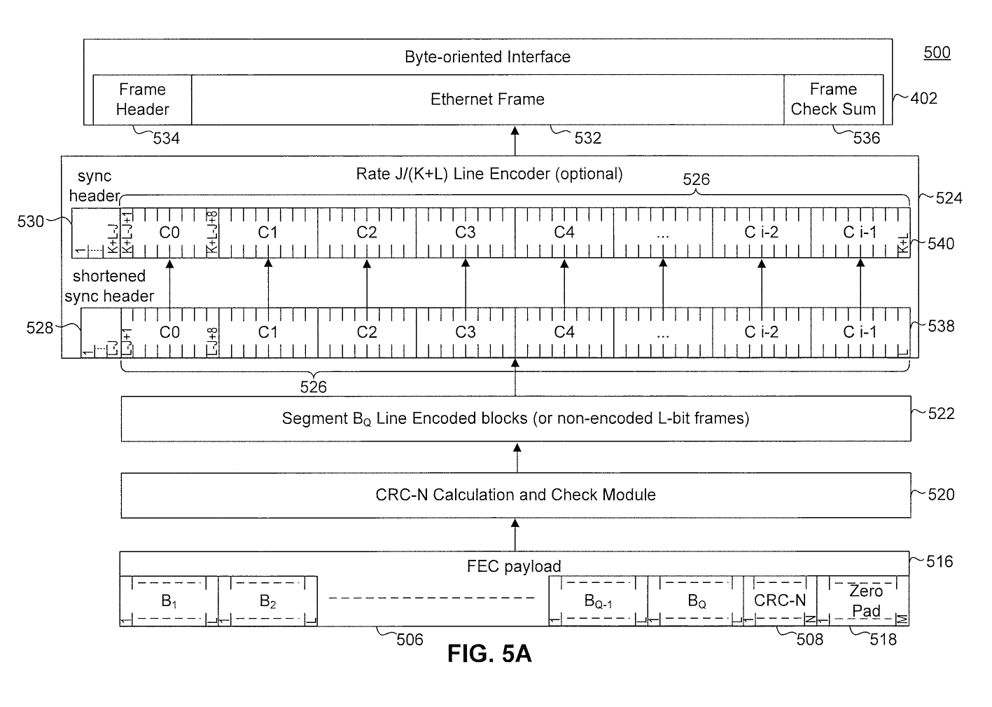

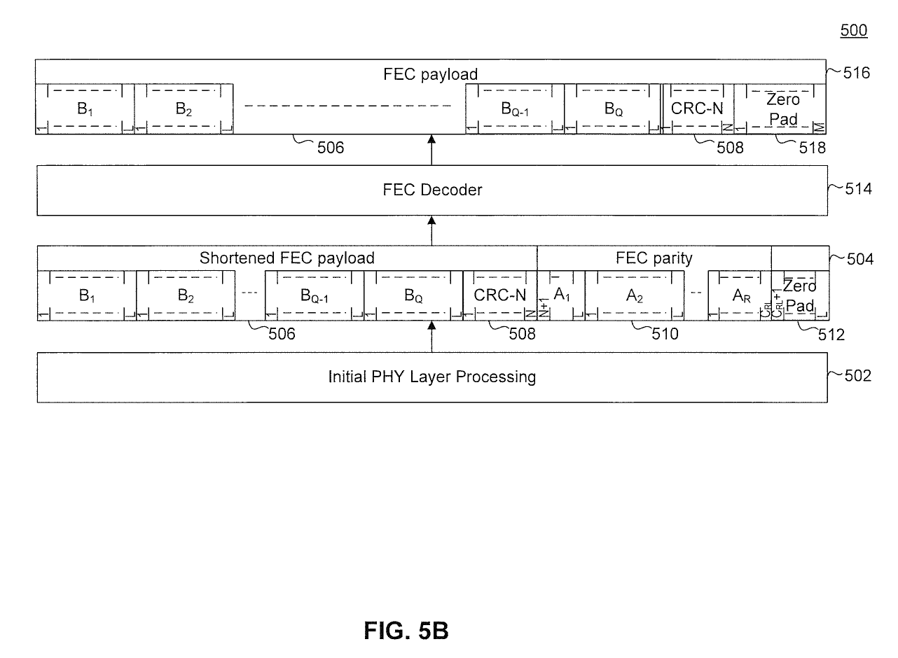

FIGS. 5A-5B illustrate an example PHY device 500 according to an embodiment. Example PHY device 500 is provided for the purpose of illustration only and is not limiting of embodiments. Example PHY device 500 can be an embodiment of EPoC PHY 224, EPoC PHY 232, or EPoC PHY 306 described above, and can be used to perform a PHY decoding scheme according to an embodiment. In an embodiment, PHY device 500 includes interface circuitry 402 and processing circuitry for implementing at least a lower PHY processing module 502, an FEC decoder 514, a CRC-N calculation and check module 520, a buffer 522, and a line decoder 524.

As shown in FIG. 5B, operation in PHY device 500 begins with lower PHY processing module 502 forwarding an FEC codeword 504 to FEC decoder 514. FEC codeword 504 includes a shortened FEC payload composed of B_{Q} data blocks 506 and an N-bit CRC sequence 508, FEC parity bits 510, and zero padding bits 512. In an embodiment, zero padding bits 512 are removed and the shortened FEC payload is padded by zero padding bits 518 to full payload size (k bits) and then decoded by FEC decoder 514 using FEC parity bits 510. The output of FEC decoder 514 is an error-corrected FEC payload 516, including data blocks 506, N-bit CRC sequence 508, and zero padding bits 518. Zero padding bits 518 are then removed and the remaining data blocks 506 and N-bit CRC sequence 508 are provided to CRC-N calculation and check module 520.

As shown in FIG. 5A, CRC-N calculation and check module 520 computes an N-bit CRC sequence based on data blocks 506 and compares the computed N-bit CRC sequence to N-bit CRC sequence 508. As would be understood by a person of skill in the art based on the teachings herein, a CRC check can be performed in several different ways other than a direct calculation and comparison of the actual N-bit CRC values. Depending on the CRC check outcome, data blocks 506 are passed to line decoder 524 with or without an error indication as further described below.

In an embodiment, data blocks 506 are provided to buffer 522 where they are segmented into L-bit encoded blocks. As shown in FIG. 5A, each L-bit encoded block 538 includes a J-bit data block 526 and a shortened synchronization header 528 of size L−J. In an embodiment, line decoder 524 is a rate J/(K+L) line encoder. As such, each L-bit encoded block 538 is increased by adding K bits to its synchronization header before decoding by line decoder 524. This results in each data block 540 input to line decoder 524 having a total size K+L, including a reconstituted K+L−J synchronization header 530 and a J-bit data block 526.

In an embodiment, CRC error indication is signaled to line decoder 524 in reconstituted synchronization header 530 of one or more of data blocks 540 associated with the CRC check. Specifically, if the N-bit CRC sequence computed by CRC-N calculation and check module 520 matches N-bit CRC sequence 508, then reconstitution header 530 of each of data blocks 540 is formed by the addition of a valid bit set to shortened synchronization header 528. This results in a valid synchronization header 530 associated with each of data blocks 540, and each of data blocks 540 is accordingly identified as a valid line encoded data blocks by line decoder 524.

Otherwise, if the N-bit CRC sequence computed by CRC-N calculation and check module 520 does not match N-bit CRC sequence 508, then reconstitution header 530 of each of data blocks 540 (or of a subset of data blocks 540 in another embodiment) is formed by the addition of an invalid bit set to shortened synchronization 528. This results in an invalid synchronization header 530 associated with each of data blocks 540 (or the subset of data blocks 540). Each of data blocks 540 (or the subset of data blocks 540) is then identified as an invalid line encoded data block by line decoder 524. In an embodiment, where only a subset of data blocks 540 is marked with an error indication, the subset is selected so that every Ethernet frame resulting from the assembly of data blocks 540 after decoding (under a minimum size Ethernet frame assumption) is corrupted and thus can be identified as erroneous by the MAC layer.

Line decoder 524 decodes data blocks 540 to generate line decoded data blocks. Data blocks 540 with valid synchronization header 530 are decoded and passed to interface circuitry 402 where they are assembled into MAC frames, each having a frame header 534, and Ethernet frame 532, and a FCS 536. Data blocks 540 with invalid synchronization header 530 are identified as invalid by line decoder 524 and are discarded and not forwarded to interface circuitry 402. The resulting stream of MAC frames assembled in interface circuitry 402 would have gaps in the locations of the discarded data blocks.

In another embodiment of PHY device 500, line decoder 524 is not used. As such, CRC-N calculation and check module 520 passes or discards each of data blocks 506 (or a subset of data blocks 506) based on the CRC check outcome. For example, if the N-bit CRC sequence computed by CRC-N calculation and check module 520 does not match N-bit CRC sequence 508, CRC-N calculation and check module 520 can discard every data block 506 associated with the CRC check or a subset of data blocks 506 as described above. Otherwise, CRC-N calculation and check module 520 passes every data block 506 to interface circuitry 402.

In embodiments, the length N of N-bit CRC sequence 424 added by CRC-N calculation module 420 of PHY device 400 is selected to be long enough to insure the standard required MTTFPA is achieved. In the following, mathematical analysis describing the selection of the length N of N-bit CRC sequence 424 according to embodiments is described. Because the MTTFPA can vary depending on transmission characteristics, the analysis selects the value of N such that the minimum possible MTTFPA (worst case condition) is greater than the standard required MTTFPA. This ensures that the MTTFPA is satisfied under all conditions.

The analysis recognizes that the MTTFPA is the inverse of the false packet acceptance ratio (FPAR) times the Ethernet frame rate R (MTTFPA=1/(FPAR*R)). The FPAR is a standard set constant value. Thus, the minimum MTTFPA occurs when the Ethernet frame rate R is maximized, which for a fixed PHY bit rate B results when the transmitted stream consists entirely of smallest size Ethernet frames (64 bytes).

For an Ethernet packet error (or frame loss) ratio much smaller than one, the FPAR can be written as:

FPAR=FLR*Q/2^{(N+32)} (1)

where FLR is the Ethernet frame loss ratio, Q represents the number of minimum size Ethernet frames (including header and FCS) per FEC payload, and (N+32) represents the sum of the length N of N-bit CRC sequence 424 and the length (32 bits) of the FCS per Ethernet frame.

The Ethernet frame rate R (in bits per second) can be written as:

$$R = \frac{B}{8 * ( 64 + H + IFG )} \qquad ( 2 )$$

where B represents the PHY link bit rate, H represents the number of header bytes, IFG represents the size in bytes of the inter-frame gap, and 64 is the number of bytes in a minimum size Ethernet frame.

With the MTTFPA being the inverse of the FPAR times the Ethernet frame rate R, the MTTFPA can be written as:

$$MTTFPA - 1 / ( FPAR * R ) - 1 / ( FLR * Q * {2}^{- ( N + 32 )} * \frac{B}{8 * ( 64 + H + IFG )} ) \qquad ( 3 )$$

Equation (3) provides the relationship between the MTTFPA and N based on values of the PHY layer bit rate B, the desired FLR, and the number of minimum size Ethernet frames per FEC payload, Q. The minimum value of N for CRC sequence 424 that achieves the required MTTFPA (for the worst case condition corresponding to the maximum Ethernet frame rate) can be calculated by solving for N in equation (3), resulting in:

$$N \geq \frac{log [ MTTFPA * Q * FLR * \frac{B}{8 * ( 64 + H + IFG )} * {2}^{- 32} ]}{log [ 2 ]} \qquad ( 4 )$$

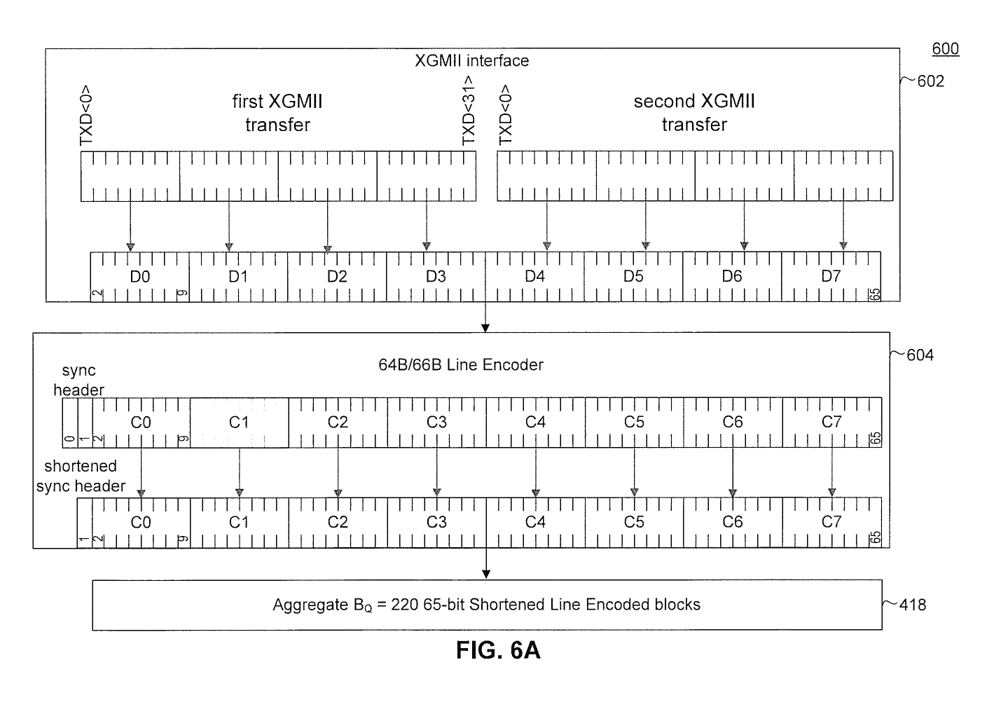

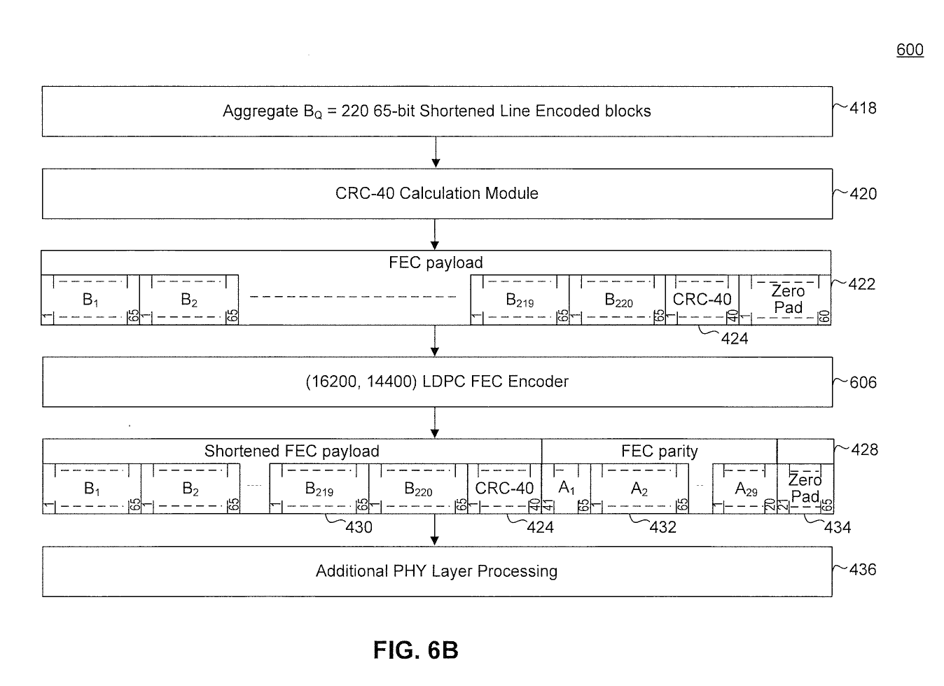

FIGS. 6A-6B illustrates another example PHY device 600 according to an embodiment. Example PHY device 600 is provided for the purpose of illustration only and is not limiting of embodiments. Example PHY device 600 can be an embodiment of example PHY device 400 described above. Specifically, as shown in FIGS. 6A-6B, interface circuitry 402, line encoder 410, and FEC encoder 426 are embodied respectively by an XGMII interface 602, a 64B/66B line encoder 604, and a (16200, 14400) LDPC FEC encoder 606.

Processing of a received stream of MAC frames by XGMII interface 602 is as described above with respect to interface circuitry 402. In an embodiment, 64-bit data blocks are assembled from the stream of MAC frames. Each of the 64-bit data blocks is processed by line encoder 604, which adds a two bit synchronization header to the data block to generate a 66-bit data block. The synchronization header contains two bits which are the complement of each other (i.e., “01” or “10”). Subsequently, the synchronization header of each 66-bit data block is shortened by removing either the first bit or the second bit, to generate a 65-bit data block.

Buffer 418 aggregates 220 65-bit data blocks and provides them to CRC calculation module 420. In an embodiment, CRC calculation module 420 computes a 40-bit CRC sequence based on the 220 65-bit data blocks and appends the 40-bit CRC sequence to the 220 65-bit data blocks. In an embodiment, a generator polynomial of the 40-bit CRC sequence is equal to x⁴⁰+x²⁶+x²³+x¹⁷+x³+1. Zero padding can then be added to form FEC payload 422 as described above with respect to FIG. 4A.

In an embodiment, FEC payload 422 is 14400 bits long. With 40 bits reserved for the 40-bit CRC, the number of line encoded 65-bit blocks that can be fitted per FEC payload is equal to (14400−40)/65=220.9 blocks. Since only a whole number of 65-bit line encoded blocks can be carried in an FEC payload, only 220 such 65-bit blocks are carried with 40 bits of CRC. This leaves (14400−65*220−40)=60 bits of zero pad in the remainder of FEC payload 422.

FEC payload 222 is then provided to FEC encoder 606, which encodes FEC payload 422 to generate an FEC codeword 428. Specifically, FEC encoder 606 adds 1800 parity bits 432 to FEC payload 422. The zero padding bits from the payload portion are then removed. This results in an output codeword length of (14400+1800−60)=(16200−60)=16140 bits. Since 16140/65=248.3, the parity bits 432 are zero padded with 45 zero padding bits 434 (249*65−16140=16185−16140=45) to complete the last 65-bit block. The resulting 249 65-bit blocks are then transferred to the lower physical sub-layers for additional processing and transmission over the link.

As further shown below, the PHY encoding scheme of example PHY device 600 satisfies the MTTFPA (MTTFPA greater than the lifetime of the universe or 4.4×10¹⁷ seconds) for downstream requirements of a 10 Gbps EPoC link data rate (B) and an Ethernet frame error ratio at the FEC decoder (or equivalently a Frame Loss Ratio (FLR) at the receiver's MAC-PHY interface) less than or equal to 10⁻⁶. As described above, the MTTFPA is calculated for the worst case condition corresponding to a minimum Ethernet frame size of 64 bytes. Additionally, it is assumed that the Ethernet frame header H is an 8 byte EPON header and that the IFG is 12 bytes.

From equation (2) above, this results in an Ethernet frame rate R equal to:

$$R = \frac{10 \times {10}^{9}}{8 * ( 64 + 8 + 12 )} = 14.88 \times {10}^{6}$$

packets per second. The number of minimum size Ethernet frames (including header and FCS) per FEC payload can be computed according to:

$$Q = ⌊ \frac{⌊ 14400 / 65 ⌋}{( 64 + 8 )} * \frac{65}{8} ⌋ + 2 = 26.$$

Then, from equation (3) above, the MTTFPA for this example embodiment can be computed as:

$$MTTFPA = 1 / ( 26 * {10}^{- 6} * {2}^{- ( 40 + 32 )} * \frac{10 \times {10}^{9}}{8 * ( 64 + 8 + 12 )} ) = 1.22 \times {10}^{19}$$

which is greater than the required age of the universe MTTFPA of 4.4×10¹⁷ seconds. Using similar calculation, it can be shown that the MTTFPA is also satisfied for upstream requirements of a 5 Gbps EPoC link data rate and a FLR less than or equal to 5×10⁻⁵. For greater upstream data rate, a larger size CRC can be used and/or the FLR requirement can be relaxed.

It is noted that in this example the minimum value of N to achieve the desired MTTFPA can be computed using equation (4) above as follows:

$$N \geq \frac{log [ 4.4 \times {10}^{17} * 26 * {10}^{- 6} * \frac{10 \times {10}^{9}}{8 * ( 64 + 8 + 12 )} * {2}^{- 32} ]}{log [ 2 ]} = 35.2$$

Accordingly, a CRC sequence of size equal to at least 36 bits can be used according to embodiments in order to satisfy the standard required MTTFPA.

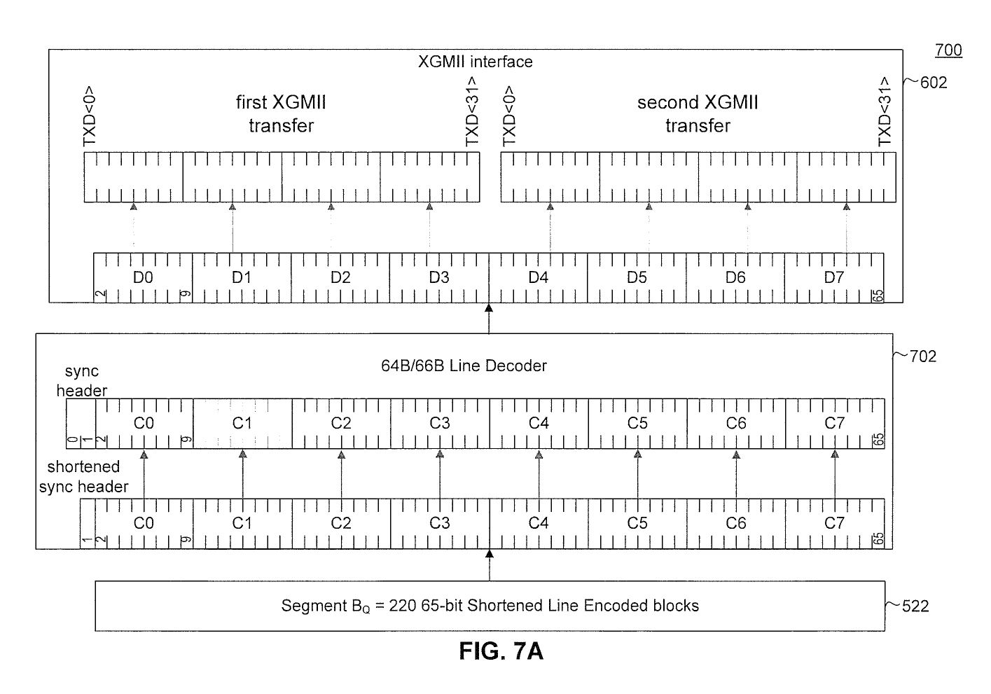

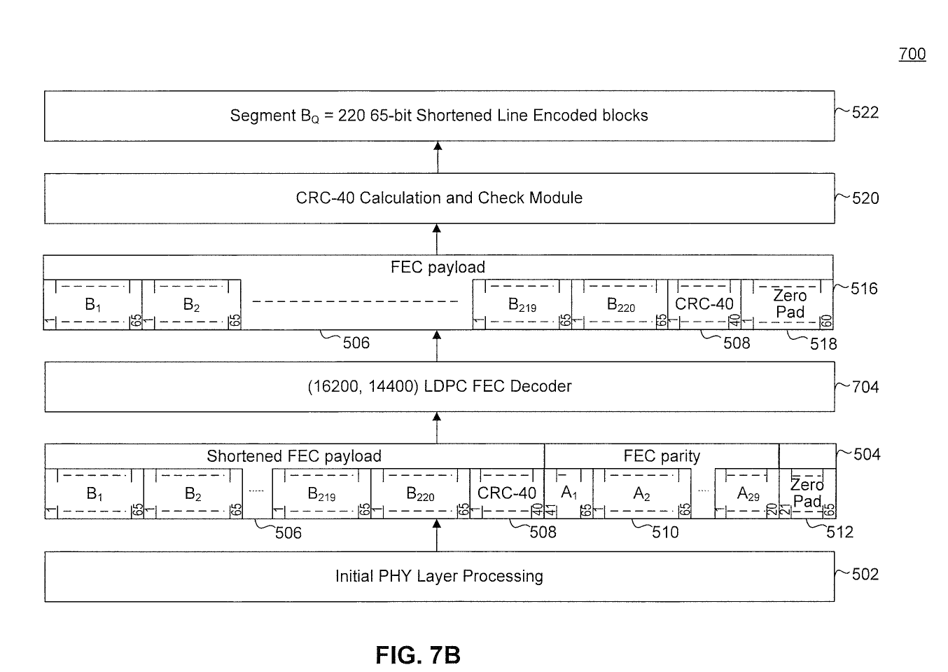

FIGS. 7A-7B illustrate another example PHY device 700 according to an embodiment. Example PHY device 700 is provided for the purpose of illustration only and is not limiting of embodiments. Example PHY device 700 can be an embodiment of example PHY device 500 described above. Specifically, as shown in FIGS. 7A-7B, interface circuitry 402, line decoder 524, and FEC decoder 514 are embodied respectively by XGMII interface 602, a 64B/66B line decoder 702, and a (16200, 14400) LDPC FEC decoder 704.

As described above with respect to example PHY device 500, operation in example PHY device 700 begins with lower PHY processing module 502 forwarding an FEC codeword 504 to FEC decoder 704. In an embodiment, FEC codeword 504 includes a shortened FEC payload composed of 220 65-bit data blocks 506 and a 40-bit CRC sequence 508, FEC parity bits 510, and zero padding bits 512. In an embodiment, zero padding bits 512 are removed and the shortened FEC payload is padded by zero padding bits 518 to full payload size (16200 bits) and then decoded by FEC decoder 704 using FEC parity bits 510. The output of FEC decoder 704 is an error-corrected FEC payload 516, including data blocks 506, 40-bit CRC sequence 508, and zero padding bits 518. Zero padding bits 518 are then removed and the remaining data blocks 506 and N-bit CRC sequence 508 are provided to CRC-N calculation and check module 520.

CRC-N calculation and check module 520 computes a 40-bit CRC sequence based on the error corrected 65-bit data blocks 506 and compares the computed 40-bit CRC sequence to 40-bit CRC sequence 508. If the CRC check passes, the shortened 1-bit synchronization header of each of the 65-bit data blocks 506 is reconstituted to a 2-bit synchronization header by adding the complement of the 1-bit header to the data block. If the 1-bit synchronization header includes the value “0” then a bit with the value “1” is added, and vice versa. Otherwise, if the CRC check fails, the shortened 1-bit synchronization header of each of the 65-bit data blocks 506 is reconstituted to a 2-bit synchronization by adding a bit of same value as the 1-bit header to the data block. If the 1-bit synchronization header includes the value “0” (“1”) then a bit with the value “0” (“1”) is added. Because a valid 2-bit synchronization header includes complementary bit values, a “00” or a “11” indicates an invalid header to line decoder 702. In another embodiment, only a subset of data blocks 506 are reconstituted with invalid headers when the CRC check fails. As described above, the subset is selected such that every Ethernet frame resulting from data blocks 506 is corrupted and thus can be identified as erroneous by the MAC layer.

Line decoder 702 decodes the data blocks to generate line decoded data blocks. Data blocks with valid synchronization headers are decoded and passed to XGMII interface 602 where they are assembled into MAC frames and forwarded to the MAC layer. Data blocks with invalid synchronization headers are identified as invalid by line decoder 702 and are discarded and not forwarded to XGMII interface 602.

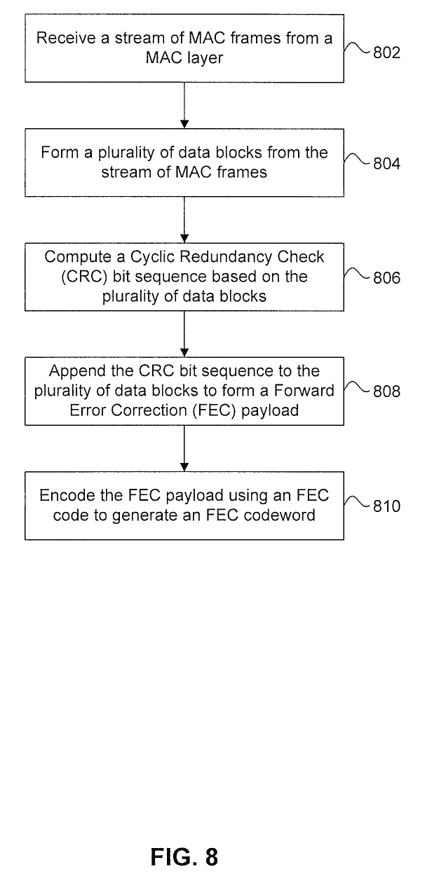

FIG. 8 illustrates an example PHY encoding process 800 according to an embodiment. Process 800 is provided for the purpose of illustration only and is not limiting of embodiments. Process 800 can be performed by a PHY device, such as EPoC PHY 224, EPoC PHY 232, EPoC PHY 306, PHY device 400, or PHY device 600, for example.

As shown in FIG. 8, process 800 begins in step 802, which includes receiving a stream of MAC frames from a MAC layer module. In an embodiment, step 802 is performed by interface circuitry such as interface circuitry 402 described above with respect to FIG. 4A. In an embodiment, the MAC frames include EPON frames. In another embodiment, step 802 includes receiving the stream of MAC frames from a PHY device.

Process 800 then proceeds to step 804, which includes forming a plurality of data blocks from the stream of MAC frames. In an embodiment, step 804 includes generating a plurality of first data blocks from the stream of MAC frames. In an embodiment, each of the plurality of first data blocks is J-bit long. Then, step 804 includes line encoding each of the plurality of first data blocks to generate a respective plurality of line encoded data blocks. In an embodiment, the plurality of first data blocks are line encoded using a line code of rate J/(K+L). Finally, step 804 includes shortening a synchronization header of each of the plurality of line encoded data blocks to generate the plurality of data blocks. In an embodiment, the synchronization header of each of the plurality of line encoded data blocks is shortened from (K+L−J) to (L−J) bits so that the resulting plurality of data blocks are L bits each.

Subsequently, in step 806, process 800 includes computing a CRC bit sequence based on the plurality of data blocks. In an embodiment, the CRC bit sequence is at least 36 bits long. In another embodiment, a generator polynomial of the CRC bit sequence is equal to x⁴⁰+x²⁶+x²³+x¹⁷+x³+1. Then, step 808 includes appending the CRC bit sequence to the plurality of data blocks to form an FEC payload.

Process 800 terminates in step 810, which includes encoding the FEC payload using an FEC code to generate an FEC codeword. In an embodiment, the FEC code is a soft decision code, such as an LDPC code. In another embodiment, process 800 can further include transmitting the FEC codeword over an EPoC to a second PHY device. As a result of PHY encoding process 800, a MTTFPA associated with the stream of MAC frames at the second PHY device is greater than 4.4×10¹⁷ seconds.

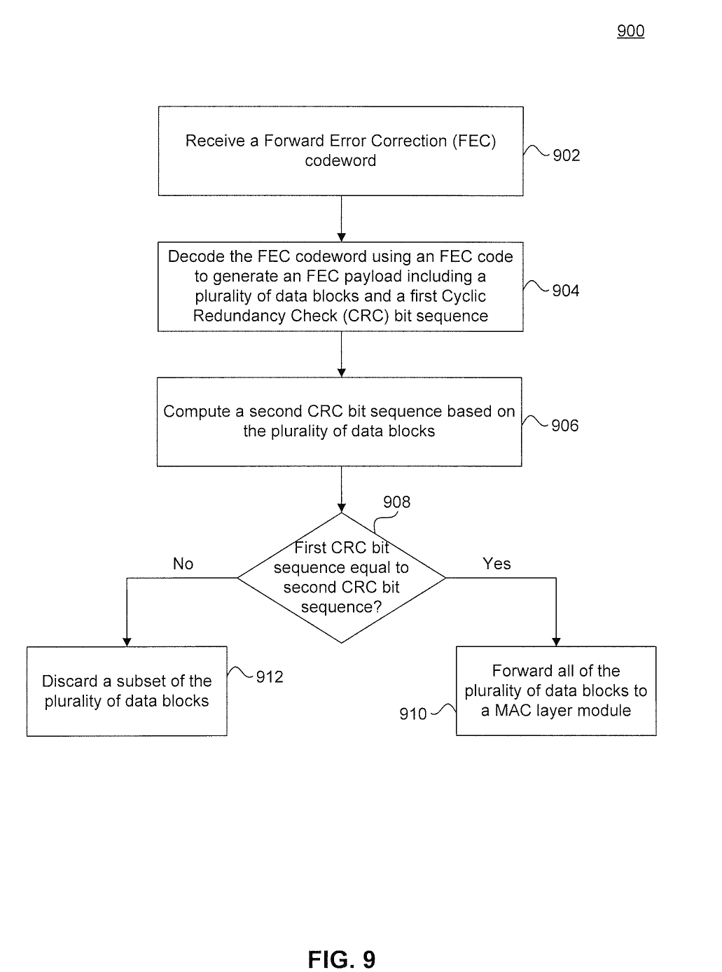

FIG. 9 illustrates an example PHY decoding process 900 according to an embodiment. Process 900 is provided for the purpose of illustration only and is not limiting of embodiments. Process 900 can be performed by a PHY device, such as EPoC PHY 224, EPoC PHY 232, EPoC PHY 306, PHY device 500, or PHY device 700, for example.

As shown in FIG. 9, process 900 begins in step 902, which includes receiving an FEC codeword. In an embodiment, the FEC codeword is received from lower PHY processing circuitry of the PHY device, which are in communication with another PHY device.

Process 900 then proceeds to step 904, which includes decoding the FEC codeword using an FEC code to generate an FEC payload. In an embodiment, the FEC codeword is encoded such that the FEC payload includes a plurality of data blocks and a first CRC bit sequence.

Subsequently, step 906 includes computing a second CRC bit sequence based on the plurality of data blocks. In an embodiment, step 906 includes using the same CRC code as used to generate the first CRC bit sequence by the transmitting side of the FEC codeword.

Process 900 then proceeds to step 908, which includes comparing the first CRC bit sequence with the second CRC bit sequence. If the first CRC bit sequence is equal to the second CRC bit sequence, process 900 proceeds to step 910, which includes forwarding all of the plurality of data blocks to a MAC layer module.

Otherwise, if the first CRC bit sequence is not equal to the second CRC bit sequence, process 900 proceeds to step 912, which includes discarding a subset of the plurality of data blocks. In an embodiment, the subset corresponds to all of the plurality of data blocks. The discarded subset of the plurality of data blocks is not forwarded to the MAC layer module. In an embodiment, the plurality of data blocks include a plurality of MAC frames and the subset is selected such that discarding it causes an error in every one of the plurality of MAC frames.

In an embodiment, when the first CRC bit sequence is not equal to the second CRC bit sequence, step 912 further includes marking the subset of the plurality of data blocks with an error indication. For example, in an embodiment, where the plurality of data blocks are line encoded, step 912 includes attaching an invalid line encoding synchronization header to each data block of the subset of the plurality of data blocks.

For purposes of this discussion, the term “module” shall be understood to include at least one of software, firmware, and hardware (such as one or more circuits, microchips, processors, or devices, or any combination thereof), and any combination thereof. In addition, it will be understood that each module can include one, or more than one, component within an actual device, and each component that forms a part of the described module can function either cooperatively or independently of any other component forming a part of the module. Conversely, multiple modules described herein can represent a single component within an actual device. Further, components within a module can be in a single device or distributed among multiple devices in a wired or wireless manner.

For the purposes of this discussion, the term “processor circuitry” shall be understood to include one or more: circuit(s), processor(s), or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to embodiments described herein. Alternatively, the processor can access an internal or external memory to retrieve instructions stored in the memory, which when executed by the processor, perform the corresponding function(s) associated with the processor.

Embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of embodiments of the present disclosure should not be limited by any of the above-described exemplary embodiments as other embodiments will be apparent to a person of skill in the art based on the teachings herein.

What is claimed is:

1. A physical layer (PHY) device, comprising:
interface circuitry configured to receive a stream of MAC frames from a Medium Access Control (MAC) layer module; and
processing circuitry configured to:
form a plurality of data blocks from the stream of MAC frames;
compute a Cyclic Redundancy Check (CRC) bit sequence based on the plurality of data blocks;
append the CRC bit sequence to the plurality of data blocks to form a Forward Error Correction (FEC) payload; and
encode the FEC payload using an FEC code to generate an FEC codeword.

2. The PHY device of claim 1, wherein the MAC frames include Ethernet Passive Optical Network (EPON) frames.

3. The PHY device of claim 1, wherein the processing circuitry is further configured to:
generate a plurality of first data blocks from the stream of MAC frames;
line encode each of the plurality of first data blocks to generate a respective plurality of line encoded data blocks; and
shorten a synchronization header of each of the plurality of line encoded data blocks to generate the plurality of data blocks.

4. The PHY device of claim 3, wherein each of the plurality of first data blocks is J bits long, and wherein the processing circuitry is configured to line encode each of the plurality of first data blocks using a line code of rate J/(K+L).

5. The PHY device of claim 4, wherein the synchronization header of each of the plurality of line encoded data blocks is (K+L−J) bits long.

6. The PHY device of claim 5, wherein the shortened synchronization header of each of the plurality of line encoded data blocks is L−J bits, and wherein each of the plurality of data blocks is L bits long.

7. The PHY device of claim 1, wherein a generator polynomial of the CRC bit sequence is equal to x⁴⁰+x²⁶+x²³+x¹⁷+x³+1.

8. The PHY device of claim 1, wherein the CRC bit sequence is at least 36 bits long.

9. The PHY device of claim 1, wherein the CRC bit sequence is 40 bits long.

10. The PHY device of claim 1, wherein the FEC code is a soft decision code.

11. The PHY device of claim 10, wherein the FEC code is a Low Density Parity Check (LDPC) code.

12. The PHY device of claim 1, wherein the processing circuitry is further configured to transmit the FEC codeword over an Ethernet Passive Optical Network over Coax (EPoC) to a second PHY device.

13. A method, comprising:
receiving a stream of MAC frames from a Medium Access Control (MAC) layer;
forming a plurality of data blocks from the stream of MAC frames;
computing a Cyclic Redundancy Check (CRC) bit sequence based on the plurality of data blocks;
appending the CRC bit sequence to the plurality of data blocks to form a Forward Error Correction (FEC) payload; and
encoding the FEC payload using an FEC code to generate an FEC codeword.

14. The method of claim 13, wherein a generator polynomial of the CRC bit sequence is equal to x⁴⁰+x²⁶+x²³+x¹⁷+x³+1.

15. The method of claim 13, wherein the CRC bit sequence is at least 36 bits long.

16. The method of claim 13, wherein the FEC code is a Low Density Parity Check (LDPC) code.

17. A physical layer (PHY) device, comprising:
processing circuitry configured to:
receive a Forward Error Correction (FEC) codeword;
decode the FEC codeword using an FEC code to generate an FEC payload, the FEC payload comprising a plurality of data blocks and a first Cyclic Redundancy Check (CRC) bit sequence;
compute a second CRC bit sequence based on the plurality of data blocks; and
compare the first CRC bit sequence with the second CRC bit sequence; and
interface circuitry configured to:
forward all of the plurality of data blocks to a Medium Access Control (MAC) layer module when the first CRC bit sequence is equal to the second CRC bit sequence; and
discard a subset of the plurality of data blocks when the first CRC bit sequence is not equal to the second CRC bit sequence.

18. The PHY device of claim 17, wherein when the first CRC bit sequence is not equal to the second CRC bit sequence, the processing circuitry is configured to mark the subset of the plurality of data blocks with an error indication.

19. The PHY device of claim 18, wherein the plurality of data blocks include a plurality of MAC frames, and wherein the processing circuitry is configured to select the subset of the plurality of data blocks such that discarding the subset causes an error in each of the plurality of MAC frames.

20. The PHY device of claim 18, wherein the plurality of data blocks are line encoded, and wherein when the first CRC bit sequence is not equal to the second CRC bit sequence, the processing circuitry is configured to attach an invalid line encoding synchronization header to each data block of the subset of the plurality of data blocks.
